(19) United States
(12) Patent Application Publication
(10) Pub. No.: US 2019/0269020 A1
(43) Pub. Date: Aug. 29, 2019

(54) SYSTEM AND METHOD FOR CONNECTING FLAT FLEXIBLE CABLE TO PRINTED CIRCUIT BOARD

(71) Applicant: Tesla, Inc., Palo Alto, CA (US)

(72) Inventors: Matthew Blum, San Francisco, CA (US); Adnan Esmail, Palo Alto, CA (US); Satyan Chandra, Mountain View, CA (US)

(73) Assignee: Tesla, Inc., Palo Alto, CA (US)

(21) Appl. No.: 16/280,280

(22) Filed: Feb. 20, 2019

Related U.S. Application Data
(60) Provisional application No. 62/634,954, filed on Feb. 26, 2018.

(51) Int. Cl. H05K 3/32; H05K 1/11; H05K 1/09; H01B 7/08

(52) U.S. Cl. CPC H05K 3/328; H05K 1/111; H05K 2203/107; H01B 7/08; H05K 2201/10356; H05K 1/09

(57) ABSTRACT

A method for connecting a cable with an electronic device is provided. The cable has multiple conductors of a first thickness, and the electronic device has multiple metal pads of a second thickness. The method includes removing a sheathing over the multiple conductors of the cable to expose the plurality of conductors. The method includes placing the exposed multiple conductors of the cable over the multiple metal pads of the electronic device. The method further includes focusing a laser beam over a portion of the multiple conductors, such that the laser beam welds each conductor to a corresponding metal pad.

### CROSS REFERENCE TO RELATED PATENTS

The present U.S. Utility patent application claims priority pursuant to 35 U.S.C. § 119(e) to U.S. Provisional Application No. 62/634,954, entitled “SYSTEM & METHOD FOR CONNECTING FLAT FLEXIBLE CABLE TO PRINTED CIRCUIT BOARD”, filed Feb. 26, 2018, which is hereby incorporated herein by reference in its entirety and made part of the present U.S. Utility patent application for all purposes.

### TECHNICAL FIELD

The present disclosure relates to printed circuit boards, and more specifically to techniques for connecting flat flexible cables to printed circuit boards.

### BACKGROUND

Connections to electronic devices are typically made using one or more cables. The cables transmit data to or from the device. They may also provide power to the device. Typically, each cable contains multiple conductors that must be connected to the device through a connection. This connection may be done via a mated connector with the cable containing either the male or female connector and the device (or other connection point) containing the other. Connections from the cable to the device may also be made directly from the cable to a printed circuit board assembly (PCBA) of the device (or connected to the device) without using a connector. This typically involves a solder. Usually, any outer sheathing is removed from the cable to expose the underlying conductors. The conductors are then spread and joined to metal pads on the PCBA using solder. The metal pads must be spaced far enough away from one another (i.e., at great enough of a pitch) such that the applied solder does not cause a short between adjacent metal pads. This increased spacing can increase materials cost and also require more space to fit the larger PCBA. Further, since the solder typically is made of a different material than the cable's conductors and the PCBA's metal pads, heterojunctions are also created at the joining portions. This may cause electrical mismatches, charge buildups, and is a potential failure point.

Therefore, there is a need to be able to join cables to devices (or other electronic components) to minimize material costs, reduce size, reduce process steps, and minimize failure points.

### SUMMARY

The present disclosure provides a method of connecting a cable having multiple conductors with an electronic device, such as a printed circuit board having multiple metal pads. The metal pads have a first thickness and the metal may be copper. The method includes exposing the cable's conductors. This may be done by removing any sheathing over the conductors. The cable's conductors have a second thickness and may be made of copper. The cable may be a flat flexible cable. The method further provides that the exposed conductors are placed over the metal pads of the printed circuit board. A laser beam is then focused over a portion of the conductor and the laser welds each conductor to its corresponding metal pad. The laser welding may occur in a raster pattern.

In embodiments, a printed circuit board assembly is provided. The printed circuit board assembly (PCBA) includes a substrate defining a surface, and a plurality of metal pads on the surface of the substrate. The metal pads have a first thickness and may be made of copper. The metal pads may have an additional plating material, such as tin or nickel, applied on top. The plurality of metal pads is connected to other internal wiring within the printed circuit board assembly to route the signals elsewhere. A cable that has multiple conductors with wrapped insulation or sheathing is also provided. Each of the multiple conductors have a second thickness and may be made of copper. The cable's multiple conductors are exposed and then connected to the metal pads of the PCBA through a laser weld.

### BRIEF DESCRIPTION OF THE FIGURES

FIG. 1 illustrates an exemplary printed circuit board assembly (PCBA) having multiple components mounted on it and a plurality of metal pads, according to certain embodiments of the invention.

FIG. 2 illustrates a flat flexible cable (FFC), according to certain embodiments of the invention.

FIG. 3 illustrates a system for connecting FFC to PCBA, according to certain embodiments of the invention.

FIG. 4 illustrates an enlarged view of a laser weld between FFC and PCB, according to certain embodiments of the invention.

Embodiments of the present disclosure and their advantages are best understood by referring to the detailed description that follows. It should be appreciated that like reference numerals are used to identify like elements illustrated in one or more of the figures, wherein showings therein are for purposes of illustrating embodiments of the present disclosure and not for purposes of limiting it.

### DETAILED DESCRIPTION

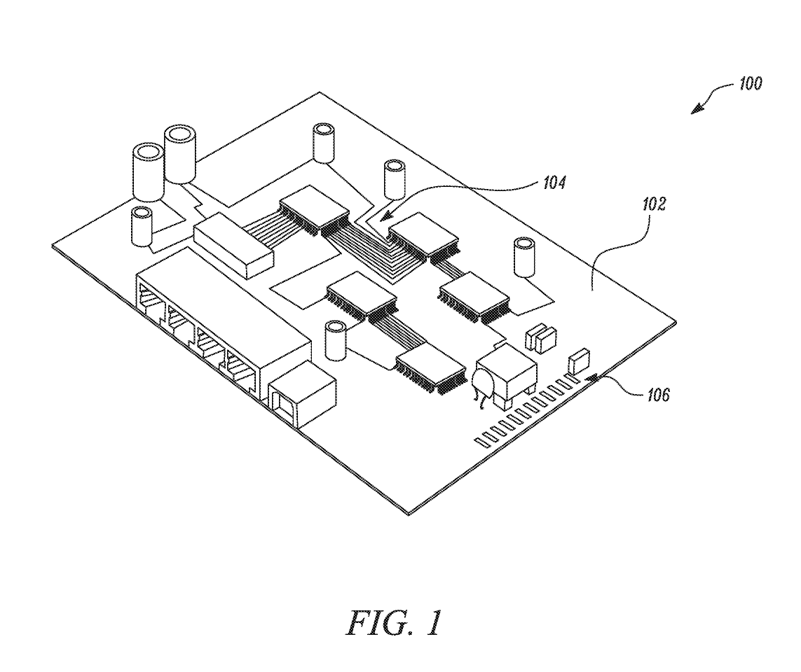

FIG. 1 shows a Printed Circuit Board Assembly (PCBA) 100. The PCBA 100 may be part of a larger sensor or device. PCBA 100 has a substrate defining a surface 102. Multiple conductive paths 104 are provided over surface 102 of PCBA 100 to transfer signals across PCBA 100 for various application requirements. PCBA 100 further has metal pads 106 for coupling PCBA 100 to another electronic device through a cable. The cable may be a flat flexible cable. Metal pads 106 may have a spacing between each pad of at least 25 microns.

In embodiments, metal pads 106 may each have at least a first thickness. The first thickness may be between 15 to 75 micrometers. In other embodiments, the first thickness is larger than 20 micrometers. Metal pads 106 are preferentially made of copper, but could be made of another metal, such as silver, gold, or another conductive metal. In embodiments, metal pads 106 are made of a non-metal, but conductive material. In embodiments, metal pads 106 have a metal coat applied on top of an underlying material (that need not be conductive), through, for example, electroplating, electrodeposition, immersion plating, or another process.

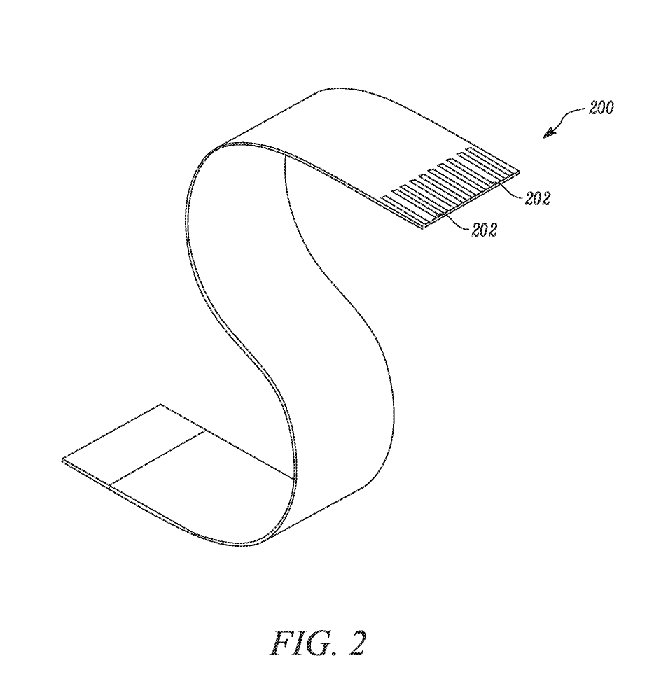

FIG. 2 illustrates a flat flexible cable (FFC) 200. FFC 200 is a cable having a plurality of conductors 202. The plurality of conductors 202 is adjacent to one another, but spaced apart from one another. Conductors 202 may be flat conductors (e.g. not cylindrical). In other embodiments, a cable with non-flat conductors may be used, such as a cable with conductors that have a circular or oval cross section. The plurality of conductors 202 have at least a second thickness and are made of a conductive material. The conductive material may be a metal, such as copper. The conductive material may be another conductive material, such as gold, silver, palladium, platinum, another conductive metal, or another conductive material. The second thickness may be between 0.30 to 0.40 millimeters. In embodiments, the second thickness is less than 0.30 millimeters. In other embodiments, the second thickness is greater than 0.40 millimeters.

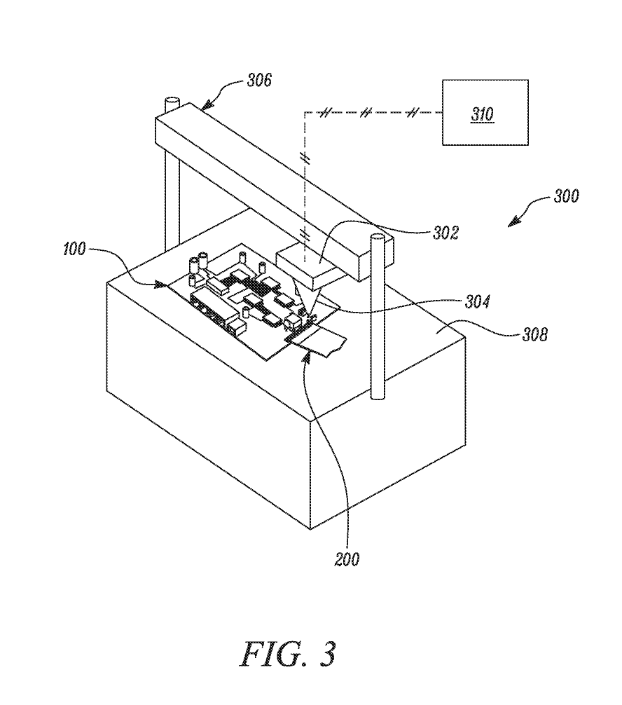

FIG. 3 shows an exemplary system 300 for coupling PCBA 100 with FFC 200 (or another cable). System 300 includes a laser source 302 which generates a focused laser beam 304. Laser source 302 may be a fiber laser source, CO₂ laser source, a Helium-Neon laser source, or any other type of a laser source which may be suitable for application with various aspects of present disclosure. In embodiments, laser source 302 generates a laser beam 304 of 20 W intensity and having a 20-micrometer beam thickness. In other embodiments, laser source 302 generates a laser beam 304 of 70 W intensity. The present disclosure is not limited by type and operating parameters of laser source 302 in any manner.

Laser source 302 is mounted with a mounting apparatus 306. Mounting apparatus 306 allows adjustment of laser source 302 such that laser beam 304 may traverse across PCBA 100, for example to form a raster pattern when performing the laser weld to weld the exposed conductors 202 of the FFC 200 to the PCBA's metal pads 106. System 300 further includes a working surface 308.

To connect PCBA 100 to FFC 200, metal pads 106 of first thickness are placed over working surface 308. Exposed conductors 202 of FFC 200 are then placed over metal pads 106. Exposed conductor 202 has a second thickness and is made of a conductive material, such as a copper, gold, silver, palladium, platinum, another conductive metal, or another conductive material. The exposed conductors 202 are aligned over metal pads 106 and the exposed conductors 202 are clamped to (or close in proximity to) the metal pads 106.

Once aligned and clamped, laser source 302 directs laser beam 304 over PCBA 100 and FFC 200 such that laser beam 304 welds portion of metal pads 106 to exposed conductors 202. Specifically, laser beam 304 heats a metal pad 106 and conductor 202 such that the materials (preferentially both made of a metal, such as a copper) melt and recrystallize locally, resulting in a welding of the metal pad 106 to the conductor 202. Laser beam 304 moves across the area where the conductor 202 overlaps with the metal pads 106. In embodiments, the laser beam 304 creates a raster pattern when welding.

Mounting apparatus 306 may have components to move the laser beam 304. Alternatively, the mounting apparatus 306 may have components to move conductors 202 and metal pad 106. In embodiments, mounting apparatus 306 is connected to an electronic controller 310 having information about laser weld parameters, first thickness, second thickness, dimensions of PCBA 100, dimensions of FFC 200, dimensions of conductors 202, and other operational parameters. Such information may be used to define an optimum path for laser beam 304 to laser weld the metal pads 106 of the PCBA 100 to the exposed conductors 202 of the FFC 200.

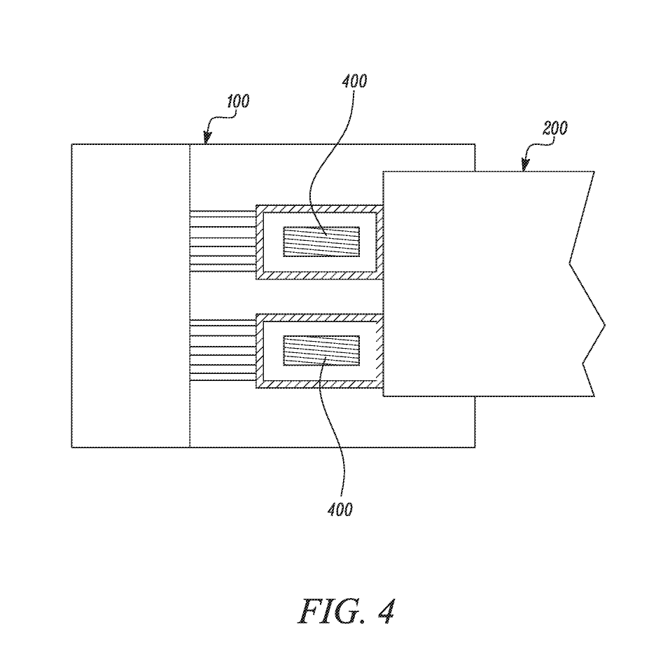

FIG. 4 shows an enlarged view of a laser weld 400 between PCBA 100 and FFC 200. Laser weld patterns can be seen through straight lines running sideways across laser weld 400. Laser weld 400 welds the metal pads 106 of the PCBA 100 to the exposed conductors 202 of the FFC 200. The laser weld 400 occurs in the area traversed by laser beam 304. In embodiments, the laser beam 304 is stationary and the PCBA 100 and FFC 200 are moved to produce the laser weld 400. Each conductor 202 can be welded to a metal pad 106 by a similar process. Working surface 308 may have adjustments to adjust the position of PCBA 100 and FFC 200 to align conductors 202 accordingly with PCBA 100, and weld conductors 202 to metal pads 106.

The present disclosure further provides a method of connecting a cable, such as FFC 200, having multiple conductors to PCBA 100. PCBA 100 has metal pads 106 that have a first thickness and width and are made of a metal, such as copper. The method includes exposing conductors 202 of FFC 200. This may be done by removing any sheathing over the conductors 202. In embodiments, the conductors 202 are exposed when the cable is manufactured (for example, the ends of the conductors 202 are not covered with a sheathing). In embodiments, conductors 202 are exposed by removing the sheathing using laser beam 304, either before welding or while the weld is being performed. The cable's conductors have a second thickness and may be made of copper. The second thickness may be between 0.3-0.4 mm. The method further provides that the exposed conductors 202 are placed over the metal pads 106 of PCBA. Laser beam 304 is then focused over a portion of the conductor 202 and the laser beam 304 welds each conductor 202 to its corresponding metal pad 106. The laser welding may occur in a raster pattern.

The systems and methods described new laser-weld techniques and the structures formed from those techniques. The welding may be automated through electronic controllers, and very precise paths may be defined for the laser beam. Through these techniques, solder may be avoided, eliminating the risk of shorting through solder connecting adjacent conductors or pads and also reducing processing steps. Further, electrical mismatches and heterojunctions may be prevented and a tighter pitch may be provided between the metal pads 106 of the PCBA 100.

The foregoing disclosure is not intended to limit the present disclosure to the precise forms or particular fields of use disclosed. As such, it is contemplated that various alternate embodiments and/or modifications to the present disclosure, whether explicitly described or implied herein, are possible in light of the disclosure. Having thus described embodiments of the present disclosure, a person of ordinary skill in the art will recognize that changes may be made in form and detail without departing from the scope of the present disclosure. Thus, the present disclosure is limited only by the claims.

In the foregoing specification, the disclosure has been described with reference to specific embodiments. However, as one skilled in the art will appreciate, various embodiments disclosed herein can be modified or otherwise implemented in various other ways without departing from the spirit and scope of the disclosure. Accordingly, this description is to be considered as illustrative and is for the purpose of teaching those skilled in the art the manner of making and using various embodiments of the disclosed air vent assembly. It is to be understood that the forms of disclosure herein shown and described are to be taken as representative embodiments. Equivalent elements, materials, processes or steps may be substituted for those representatively illustrated and described herein. Moreover, certain features of the disclosure may be utilized independently of the use of other features, all as would be apparent to one skilled in the art after having the benefit of this description of the disclosure. Expressions such as “including”, “comprising”, “incorporating”, “consisting of”, “have”, “is” used to describe and claim the present disclosure are intended to be construed in a non-exclusive manner, namely allowing for items, components or elements not explicitly described also to be present. Reference to the singular is also to be construed to relate to the plural.

Further, various embodiments disclosed herein are to be taken in the illustrative and explanatory sense, and should in no way be construed as limiting of the present disclosure. All joinder references (e.g., attached, affixed, coupled, connected, and the like) are only used to aid the reader's understanding of the present disclosure, and may not create limitations, particularly as to the position, orientation, or use of the systems and/or methods disclosed herein. Therefore, joinder references, if any, are to be construed broadly. Moreover, such joinder references do not necessarily infer that two elements are directly connected to each other.

Additionally, all numerical terms, such as, but not limited to, “first”, “second”, “third”, “primary”, “secondary”, “main” or any other ordinary and/or numerical terms, should also be taken only as identifiers, to assist the reader's understanding of the various elements, embodiments, variations and/or modifications of the present disclosure, and may not create any limitations, particularly as to the order, or preference, of any element, embodiment, variation and/or modification relative to, or over, another element, embodiment, variation and/or modification.

It will also be appreciated that one or more of the elements depicted in the drawings/figures can also be implemented in a more separated or integrated manner, or even removed or rendered as inoperable in certain cases, as is useful in accordance with a particular application. Additionally, any signal hatches in the drawings/figures should be considered only as exemplary, and not limiting, unless otherwise specifically specified.

What is claimed is:

1. A method for connecting a cable having a plurality of conductors with an electronic device having a plurality of metal pads of a first thickness, the method comprising:
removing a sheathing over the plurality of conductors of the cable to expose the plurality of conductors, wherein each conductor has a second thickness;
placing the exposed plurality of conductors of the cable over the plurality of metal pads of the electronic device; and
focusing a laser beam over a portion of the plurality of conductors, such that the laser beam welds each conductor to a corresponding metal pad.

2. The method of claim 1, wherein the cable is a flat flexible cable.

3. The method of claim 1, wherein the conductor is a flat conductor.

4. The method of claim 1, wherein the metal pads, and the conductor comprise of copper.

5. The method of claim 1, wherein the electronic device is a printed circuit board assembly (PCBA).

6. The method of claim 1, wherein the first thickness is selected from a range between 15 to 75 micrometers.

7. The method of claim 1, wherein the second thickness is selected from a range between 0.30 to 0.40 millimeters.

8. A printed circuit board assembly (PCBA) comprising:
a substrate defining a surface;
a plurality of metal pads over the surface connected to internal wiring within the PCBA for routing signals, wherein the metal pads have a first thickness; and
a cable having a plurality of conductors with wrapped sheathing, wherein each conductor from the plurality of conductors has a second thickness;
wherein the plurality of conductors of the cable is exposed by removing the sheathing, and then connected to the plurality of metal pads through a laser weld.

9. The PCBA of claim 8, wherein the cable is a flat flexible cable.

10. The PCBA of claim 8, wherein the conductor is a flat conductor.

11. The PCBA of claim 8, wherein the metal pads, and the conductor comprise of copper.

12. The PCBA of claim 8, wherein the first thickness is selected from a range between 15 to 75 micrometers.

13. The PCBA of claim 8, wherein the second thickness is selected from a range between 0.30 to 0.40 millimeters.
